(19) United States
(12) Patent Application Publication
(10) Pub. No.: US 2024/0188272 A1
(43) Pub. Date: Jun. 6, 2024

(54) METHOD FOR MANUFACTURING PILLAR-SHAPED SEMICONDUCTOR DEVICE

(71) Applicant: Unisantis Electronics Singapore Pte. Ltd., Singapore (SG)

(72) Inventor: Kenichi KANAZAWA, Tokyo (JP)

(21) Appl. No.: 18/438,725

(22) Filed: Feb. 12, 2024

Related U.S. Application Data
(63) Continuation-in-part of application No. PCT/JP2021/029827, filed on Aug. 13, 2021.

(51) Int. Cl. H10B 10/00

(52) U.S. Cl. CPC H10B 10/12

(57) ABSTRACT

In a method for forming a contact hole in electrical contact with an impurity region on a substrate present between a first semiconductor pillar and a second semiconductor pillar, a gate conductor layer at a location of the contact hole is separated into two to form a first gate conductor layer surrounding the first semiconductor pillar and a second gate conductor layer surrounding the second semiconductor pillar, and an insulating layer sidewall is formed on side walls of the first gate conductor layer and the second gate conductor layer exposed in the contact hole.

### CROSS REFERENCES TO RELATED APPLICATIONS

The present application is a continuation-in-part application of PCT/JP2021/029827, filed Aug. 13, 2021, the entire contents of which are incorporated herein by reference.

### BACKGROUND OF THE INVENTION

### 1. Field of the Invention

The present invention relates to a method for manufacturing a pillar-shaped semiconductor device.

### 2. Description of the Related Art

In recent years, three-dimensional-structure transistors have been used for large-scale integration (LSI). Of these, surrounding gate transistors (SGTs), which are pillar-shaped semiconductor devices, have attracted attention as semiconductor elements that provide semiconductor devices with high integration. In addition, there is a need for semiconductor devices including SGTs with a higher degree of integration and higher performance.

A typical planar MOS transistor has a channel extending in the horizontal direction along the upper surface of a semiconductor substrate. By contrast, an SGT has a channel extending in a direction perpendicular to the upper surface of a semiconductor substrate (see, for example, Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Thus, SGTs allow for higher densities of semiconductor devices than planar MOS transistors.

FIG. 5 shows a schematic structural view of an N-channel SGT. A semiconductor pillar 220 whose conductivity type is P-type or i-type (intrinsic type) has N⁺ layers 221a and 221b (semiconductor regions containing donor impurities in high concentrations are hereinafter referred to as “N⁺ layers”) formed in upper and lower portions of the semiconductor pillar 220, one of the N⁺ layers serving as a source, the other serving as a drain. The portion of the semiconductor pillar 220 between the N⁺ layers 221a and 221b, which serve as the source and the drain, forms a channel region 222. A gate insulating layer 223 is formed so as to surround the channel region 222. A gate conductor layer 224 is formed so as to surround the gate insulating layer 223. In the SGT, the N⁺ layers 221a and 221b, which serve as the source and the drain, the channel region 222, the gate insulating layer 223, and the gate conductor layer 224 are formed so as to have a pillar shape as a whole. Thus, in plan view, the area occupied by the SGT corresponds to the area occupied by a single source or drain N⁺ layer of a planar MOS transistor. Thus, a circuit chip including SGTs can achieve a smaller chip size than a circuit chip including planar MOS transistors. In addition, if the driving capability of SGTs can be improved, the number of SGTs used in one chip can be reduced, which also contributes to a reduction in chip size.

However, in achieving a further reduction in chip size, there is a problem to be overcome. As a matter of course, the space between adjacent semiconductor pillars becomes narrow; therefore, for example, in an upper inverter of an SRAM cell constituted by six transistors illustrated in FIGS. 1QA to 1QC, the space between 100a, which serves as an output terminal in contact with both an N⁺ layer 3 and a P⁺ layer 4a, and semiconductor pillars 6a and 6b disposed on both sides of 100a becomes significantly narrow. Likewise, in a lower inverter, the space between 100b (not illustrated), which serves as an output terminal in contact with both the N⁺ layer 3 and the P⁺ layer 4b, and semiconductor pillars 6e and 6f disposed on both sides of 100b becomes significantly narrow. Consequently, gate conductor layers 26aa, 26ab, 26ba, and 26bb formed so as to surround semiconductor pillars and conductor layers 27a and 27b forming the output terminals 100a and 100b come into electrical contact to cause a malfunction. Thus, it is necessary to reliably avoid electrical contact between gate conductor layers and output terminals.

FIG. 6 shows a diagram of a static random access memory (SRAM) cell circuit. The SRAM cell circuit includes two inverter circuits. One of the inverter circuits includes a P-channel SGT_Pc1 serving as a load transistor and an N-channel SGT_Nc1 serving as a drive transistor. The other inverter circuit includes a P-channel SGT_Pc2 serving as a load transistor and an N-channel SGT_Nc2 serving as a drive transistor. The gate of the P-channel SGT_Pc1 and the gate of the N-channel SGT_Nc1 are connected to each other. The drain of the P-channel SGT_Pc2 and the drain of the N-channel SGT_Nc2 are connected to each other. The gate of the P-channel SGT_Pc2 and the gate of the N-channel SGT_Nc2 are connected to each other. The drain of the P-channel SGT_Pc1 and the drain of the N-channel SGT_Nc1 are connected to each other.

As illustrated in FIG. 6, the sources of the P-channel SGTs_Pc1 and Pc2 are connected to a power supply terminal Vdd, and the sources of the N-channel SGTs_Nc1 and Nc2 are connected to a ground terminal Vss. Selection N-channel SGTs_SN1 and SN2 are disposed on both sides of the two inverter circuits. The gates of the selection N-channel SGTs_SN1 and SN2 are connected to a word-line terminal WLt. The source of the selection N-channel SGT_SN1 is connected to the drains of the N-channel SGT_Nc1 and the P-channel SGT_Pc1, and the drain of the selection N-channel SGT_SN1 is connected to a bit-line terminal BLt. The source of the selection N-channel SGT_SN2 is connected to the drains of the N-channel SGT_Nc2 and the P-channel SGT_Pc2, and the drain of the selection N-channel SGT_SN2 is connected to an inverted bit-line terminal BLRt. Thus, the circuit including an SRAM cell is constituted by a total of six SGTs, namely, two P-channel SGTs_Pc1 and Pc2 and four N-channel SGTs_Nc1, Nc2, SN1, and SN2 (see, for example, U.S. Patent Application Publication No. 2010/0219483). In addition, a plurality of drive transistors can be connected in parallel to increase the speed of the SRAM circuit. In general, SGTs that constitute memory cells of an SRAM are formed in different semiconductor pillars. The increase in the degree of integration of an SRAM cell circuit depends on how a plurality of SGTs can be densely formed in one cell region. The same applies to the increase in the degree of integration in the formation of other circuits including SGTs.

### SUMMARY OF THE INVENTION

In increasing the degree of integration of a circuit including SGTs, the distance between a gate conductor layer surrounding a semiconductor pillar of each SGT and a contact that is in electrical contact with an impurity region on a substrate surface adjacent to the gate conductor layer becomes significantly short to cause electrical contact between the gate conductor layer and a conductor layer forming the contact, thus causing a malfunction.

A first method for manufacturing a pillar-shaped semiconductor device according to an aspect of the present invention is a method for manufacturing a pillar-shaped semiconductor device that includes, on a substrate, a first semiconductor pillar and a second semiconductor pillar adjacent to the first semiconductor pillar, a first gate insulating layer surrounding the first semiconductor pillar, a second gate insulating layer surrounding the second semiconductor pillar, a first gate conductor layer surrounding the first gate insulating layer, a second gate conductor layer surrounding the second gate insulating layer, a first impurity region connected to a lower portion of the first semiconductor pillar, a second impurity region connected to a lower portion of the second semiconductor pillar, a third impurity region connected to a top portion of the first semiconductor pillar, a fourth impurity region connected to a top portion of the second semiconductor pillar, and a first SGT in which the first semiconductor pillar between the first impurity region and the third impurity region serves as a channel and a second SGT in which the second semiconductor pillar between the second impurity region and the fourth impurity region serves as a channel, and that has, between the first SGT and the second SGT in plan view, a first contact hole in electrical contact with at least the first or second impurity region, the method including:
a step of forming the first semiconductor pillar on the first impurity region and forming the second semiconductor pillar on the second impurity region;
a step of forming the first gate insulating layer surrounding the first semiconductor pillar and forming the second gate insulating layer surrounding the second semiconductor pillar;
a step of forming a gate conductor film so as to cover an entire surface;
a step of polishing the gate conductor film until surfaces of the top portions of the first and second semiconductor pillars are exposed;
a step of patterning an etching-mask opening region by photolithography at an inner-side region of the gate conductor film disposed between the first and second semiconductor pillars in plan view;
a step of etching the gate conductor film using the etching-mask opening region as a mask to form the first contact hole and separate the gate conductor film into the first gate conductor layer and the second gate conductor layer by the first contact hole;
a step of forming a first insulating layer so as to cover an entire surface, and anisotropically etching the first insulating layer to form a first sidewall on side walls of the first and second gate conductor layers and anisotropically etching an insulating layer including the first and second gate insulating layers and present on the substrate to expose a surface of at least the first or second impurity region; and
a step of forming a contact conductor layer so as to fill the first contact hole surrounded by the first sidewall.

The manufacturing method desirably includes: a step of, after the formation of the gate conductor film, polishing the gate conductor film until surfaces of the top portions of the first and second semiconductor pillars are exposed;
a step of recess etching the gate conductor film such that a surface of the gate conductor film is located above lower surfaces of the third and fourth impurity regions;
a step of forming a second insulating layer so as to cover an entire surface and then anisotropically etching the second insulating layer to form a second sidewall around the top portions of the first and second semiconductor pillars exposed on the gate conductor film;
a step of forming the gate conductor film so as to connect and surround both of the first and second semiconductor pillars in plan view by anisotropic etching using a photoresist formed by photolithography and the second sidewall;
a step of patterning an etching-mask opening region by photolithography at an inner-side region of the gate conductor film disposed between the first and second semiconductor pillars in plan view;
a step of anisotropically etching the gate conductor film at the etching-mask opening region using the photoresist and the second sidewall to separate the gate conductor film into the first gate conductor layer and the second gate conductor layer; and
a step of forming a first insulating layer so as to cover an entire surface, and anisotropically etching the first insulating layer to form the first sidewall on side walls of the first and second gate conductor layers and anisotropically etching an insulating layer including the first and second gate insulating layers and present on the substrate to expose a surface of at least the first or second impurity region.

The manufacturing method desirably includes,
after the step of anisotropically etching the gate conductor film at the etching-mask opening region and an insulating layer including the first and second gate insulating layers and present on the substrate to expose a surface of at least the first or second impurity region,
a step of forming a first insulating layer so as to cover an entire surface and anisotropically etching the first insulating layer to form the first sidewall on a side wall of the first contact hole.

A second method for manufacturing a pillar-shaped semiconductor device according to an aspect of the present invention is a method for manufacturing a pillar-shaped semiconductor device that includes, on a substrate, a first semiconductor pillar and a second semiconductor pillar adjacent to the first semiconductor pillar, a first gate insulating layer surrounding the first semiconductor pillar, a second gate insulating layer surrounding the second semiconductor pillar, a first gate conductor layer surrounding the first gate insulating layer, a second gate conductor layer surrounding the second gate insulating layer, a first impurity region connected to a lower portion of the first semiconductor pillar, a second impurity region connected to a lower portion of the second semiconductor pillar, a third impurity region connected to a top portion of the first semiconductor pillar, a fourth impurity region connected to a top portion of the second semiconductor pillar, and a first SGT in which the first semiconductor pillar between the first impurity region and the third impurity region serves as a channel and a second SGT in which the second semiconductor pillar between the second impurity region and the fourth impurity region serves as a channel, and that has, between the first SGT and the second SGT in plan view, a first contact hole in electrical contact with at least the first or second impurity region and the first and second gate conductor layers, the method including:
a step of forming the first semiconductor pillar on the first impurity region and forming the second semiconductor pillar on the second impurity region;
a step of forming the first gate insulating layer surrounding the first semiconductor pillar and forming the second gate insulating layer surrounding the second semiconductor pillar;
a step of forming a gate conductor film so as to cover an entire surface;
a step of polishing the gate conductor film until surfaces of the top portions of the first and second semiconductor pillars are exposed;
a step of recess etching the gate conductor film such that a surface of the gate conductor film is located above lower surfaces of the third and fourth impurity regions;
a step of forming a second insulating layer so as to cover an entire surface and then anisotropically etching the second insulating layer to form a second sidewall around the top portions of the first and second semiconductor pillars exposed on the gate conductor film;
a step of forming the gate conductor film so as to surround each of the first and second semiconductor pillars in plan view by anisotropic etching using a photoresist formed by photolithography and the second sidewall;
a step of forming a third insulating layer so as to cover an entire surface; and
a step of anisotropically etching the third insulating layer to form a first sidewall on side walls of the first gate conductor layer and the second gate conductor layer in a region where the first gate conductor layer and the second gate conductor layer face each other, and remove an insulating layer including the first and second gate insulating layers and present on the substrate to expose a surface of at least the first or second impurity region, thereby forming, as the first contact hole, a region surrounded by the first sidewall.

### BRIEF DESCRIPTION OF THE DRAWINGS

FIGS. 1AA, 1AB and 1AC are a plan view and sectional structural views for explaining a method for manufacturing a pillar-shaped semiconductor device including SGTs according to a first embodiment.

FIGS. 1BA, 1BB and 1BC are a plan view and sectional structural views for explaining a method for manufacturing a pillar-shaped semiconductor device including SGTs according to a first embodiment.

FIGS. 1CA, 1CB and 1CC are a plan view and sectional structural views for explaining a method for manufacturing a pillar-shaped semiconductor device including SGTs according to a first embodiment and a second embodiment.

FIGS. 1DA, 1DB and 1DC are a plan view and sectional structural views for explaining a method for manufacturing a pillar-shaped semiconductor device including SGTs according to a first embodiment.

FIGS. 1EA, 1EB and 1EC are a plan view and sectional structural views for explaining a method for manufacturing a pillar-shaped semiconductor device including SGTs according to a first embodiment.

FIGS. 1FA, 1FB and 1FC are a plan view and sectional structural views for explaining a method for manufacturing a pillar-shaped semiconductor device including SGTs according to a first embodiment.

FIGS. 1GA, 1GB and 1GC are a plan view and sectional structural views for explaining a method for manufacturing a pillar-shaped semiconductor device including SGTs according to a first embodiment.

FIGS. 1HA, 1HB and 1HC are a plan view and sectional structural views for explaining a method for manufacturing a pillar-shaped semiconductor device including SGTs according to a first embodiment.

FIGS. 11A, 11B and 11C are a plan view and sectional structural views for explaining a method for manufacturing a pillar-shaped semiconductor device including SGTs according to a first embodiment.

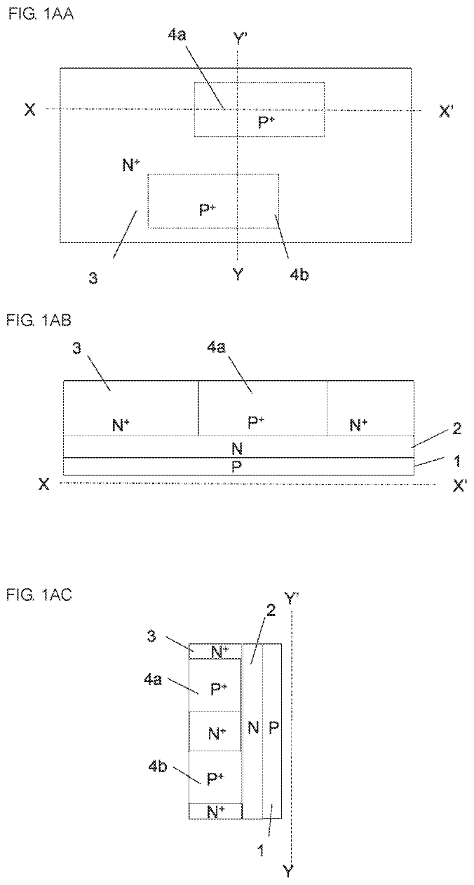

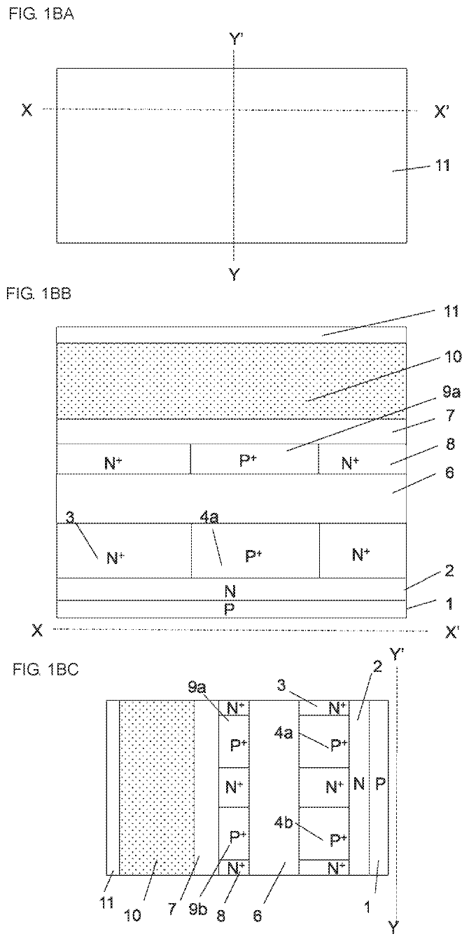

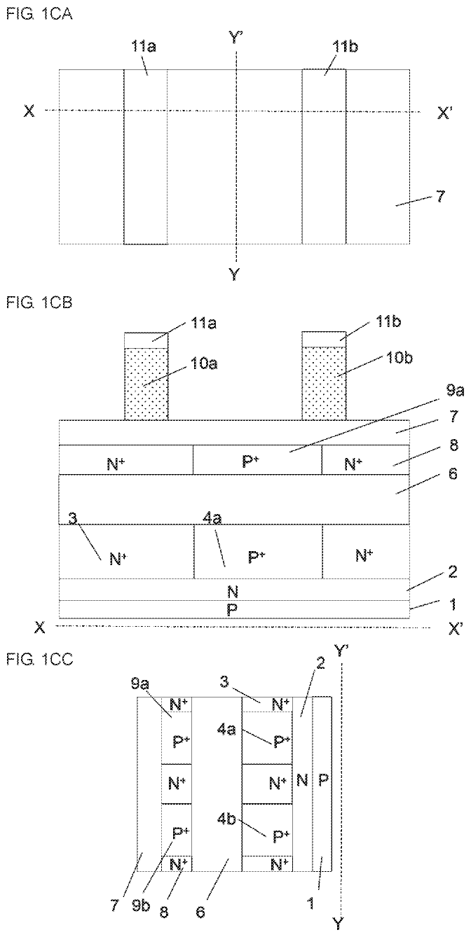

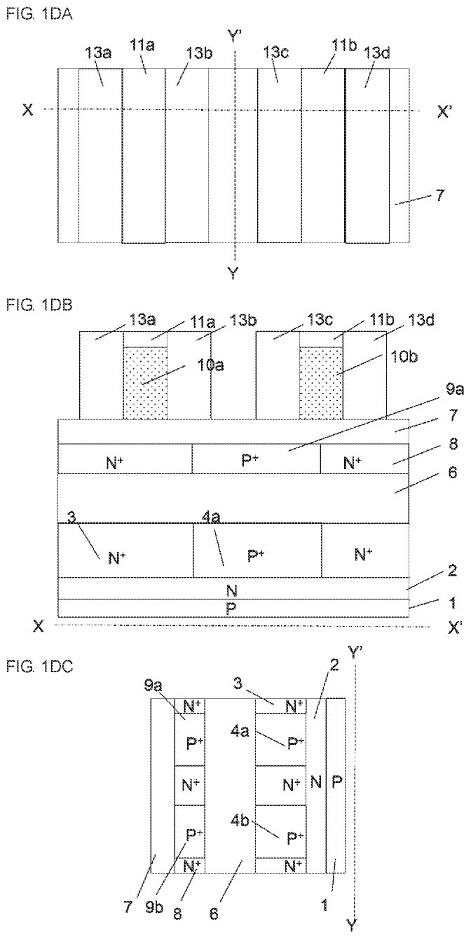

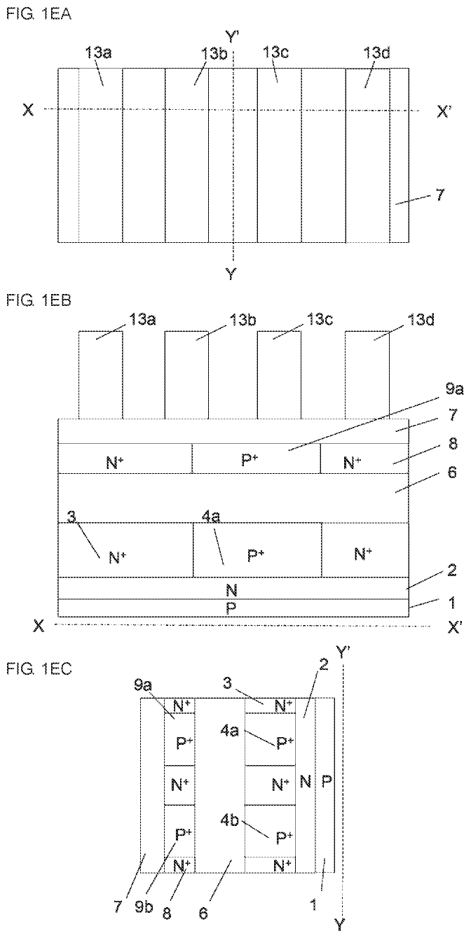

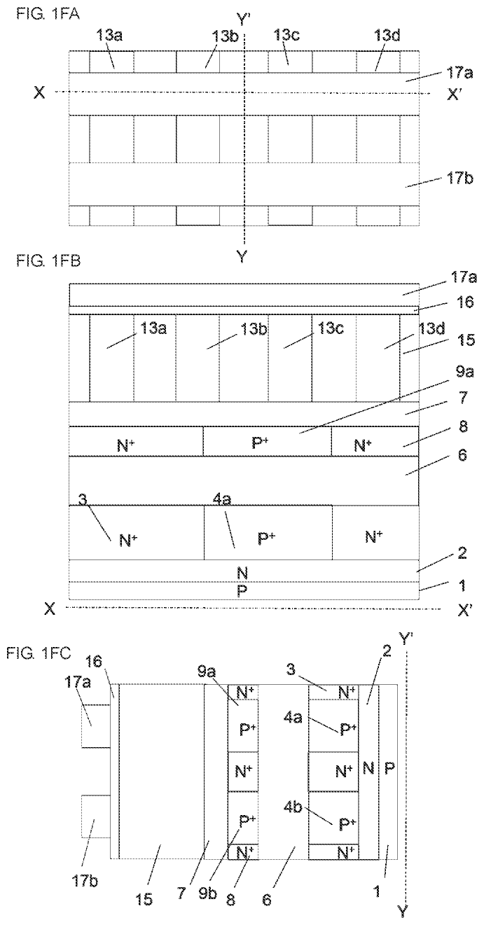

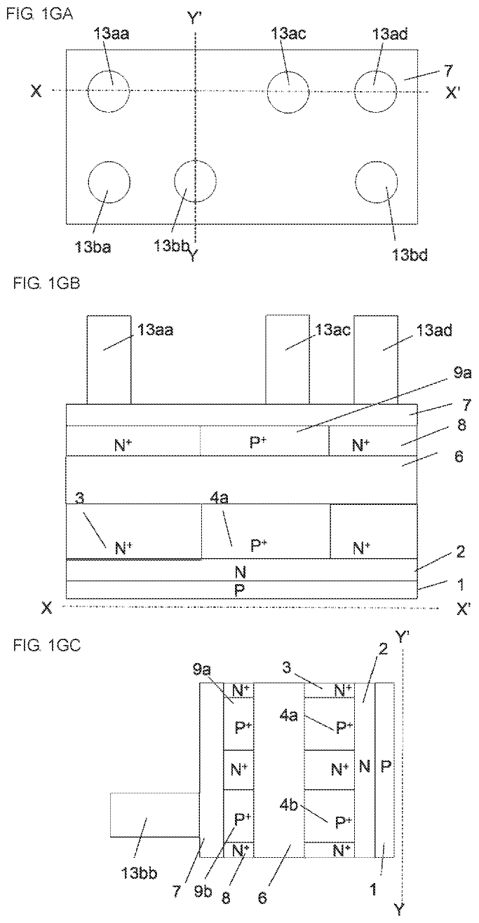

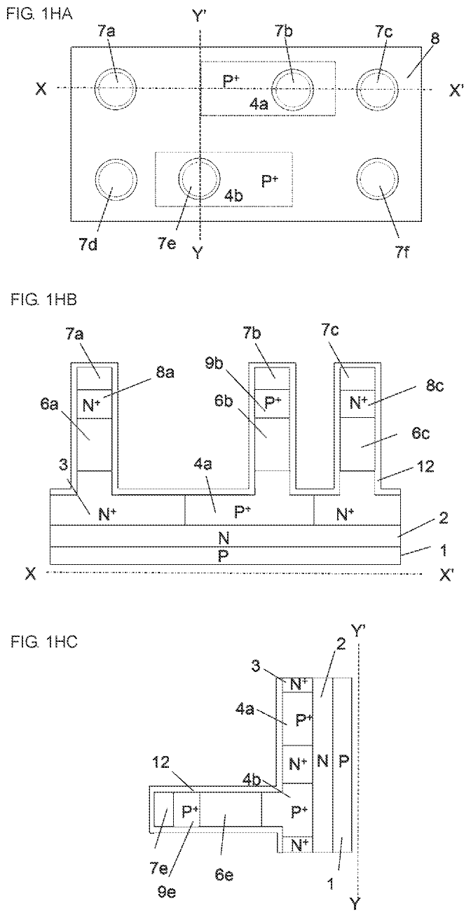

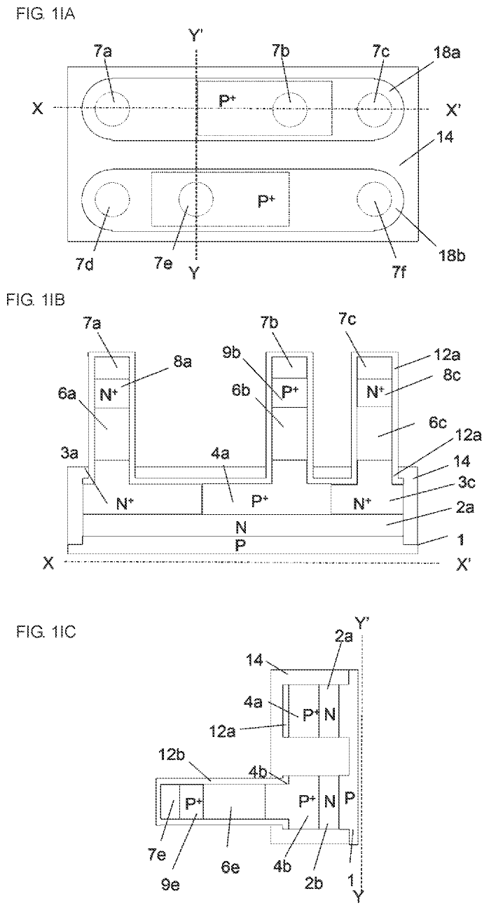

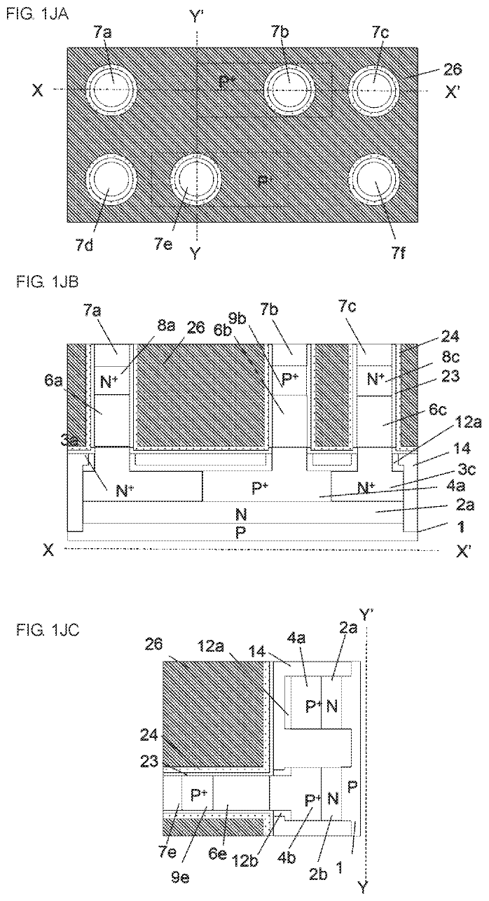

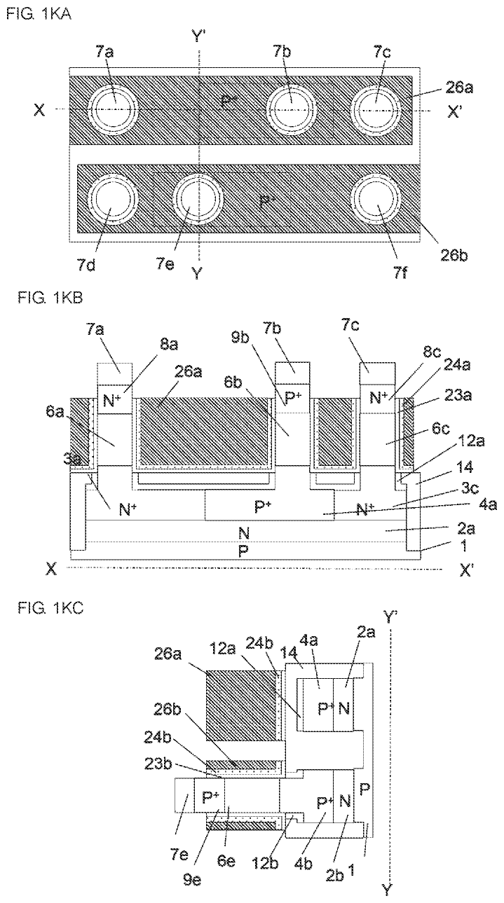

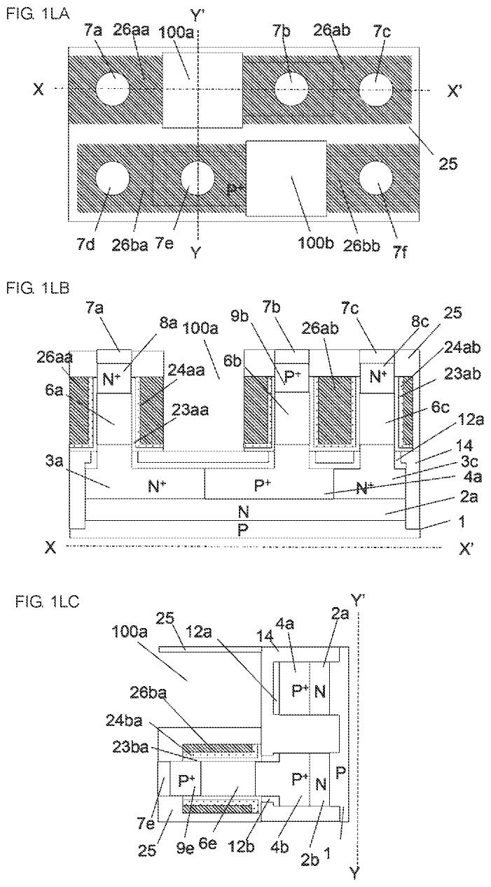

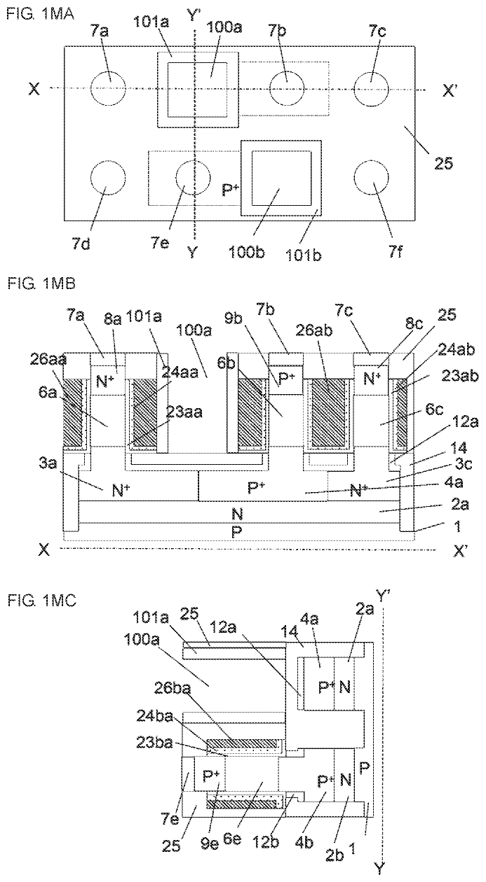

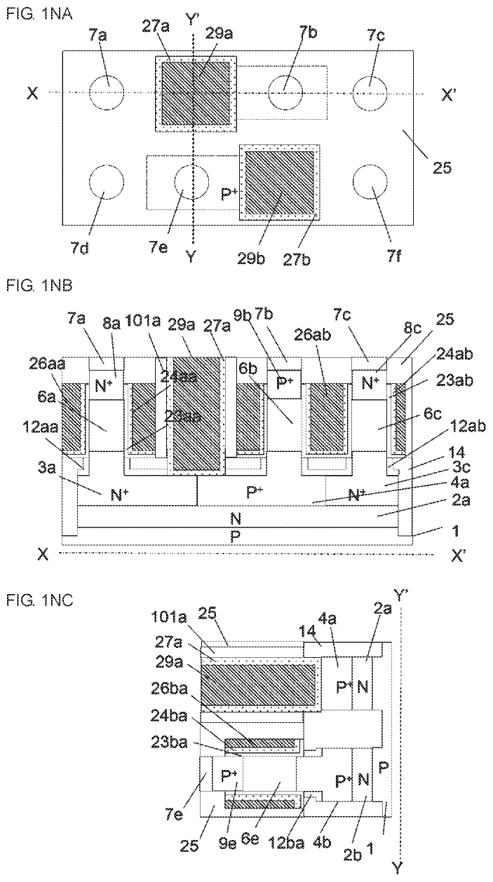

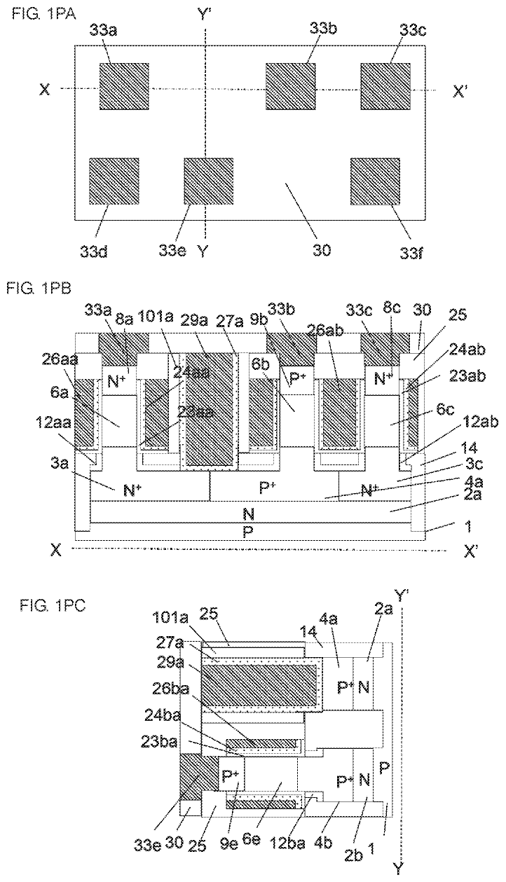

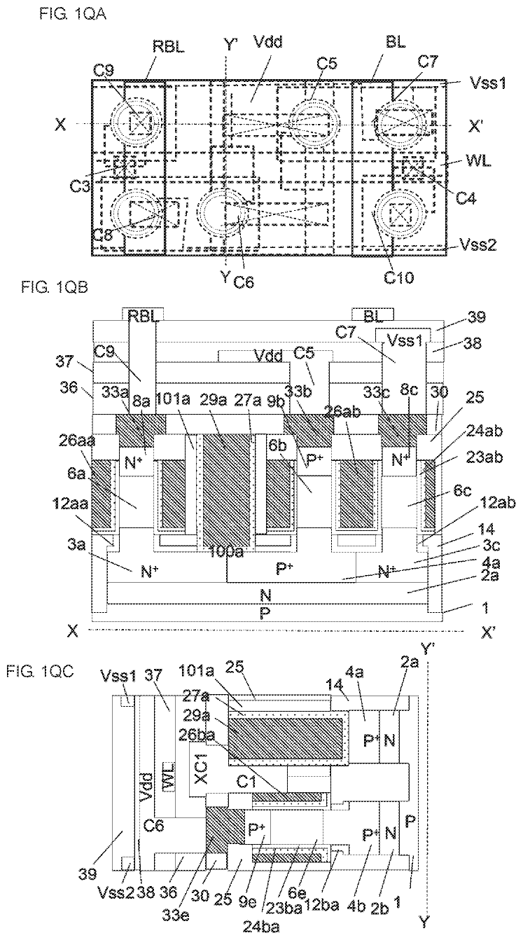

FIGS. 1JA, 1JB and 1JC are a plan view and sectional structural views for explaining a method for manufacturing a pillar-shaped semiconductor device including SGTs according to a first embodiment.

FIGS. 1KA, 1KB and 1KC are a plan view and sectional structural views for explaining a method for manufacturing a pillar-shaped semiconductor device including SGTs according to a first embodiment.

FIGS. 1LA to 1LC are a plan view and sectional structural views for explaining a method for manufacturing a pillar-shaped semiconductor device including SGTs according to a first embodiment.

FIGS. 1MA, 1MB and 1MC are a plan view and sectional structural views for explaining a method for manufacturing a pillar-shaped semiconductor device including SGTs according to a first embodiment.

FIGS. 1NA, 1NB and 1NC are a plan view and sectional structural views for explaining a method for manufacturing a pillar-shaped semiconductor device including SGTs according to a first embodiment.

FIGS. 1PA, 1PB and 1PC are a plan view and sectional structural views for explaining a method for manufacturing a pillar-shaped semiconductor device including SGTs according to a first embodiment.

FIGS. 1QA, 1QB and 1QC are a plan view and sectional structural views for explaining a method for manufacturing a pillar-shaped semiconductor device including SGTs according to a first embodiment.

FIGS. 2AA, 2AB and 2AC are a plan view and sectional structural views for explaining a method for manufacturing a pillar-shaped semiconductor device including SGTs according to a second embodiment of the present invention.

FIGS. 2BA, 2BB and 2BC are a plan view and sectional structural views for explaining a method for manufacturing a pillar-shaped semiconductor device including SGTs according to a second embodiment of the present invention.

FIGS. 2CA, 2CB and 2CC are a plan view and sectional structural views for explaining a method for manufacturing a pillar-shaped semiconductor device including SGTs according to a second embodiment of the present invention.

FIGS. 2DA, 2DB and 2DC are a plan view and sectional structural views for explaining a method for manufacturing a pillar-shaped semiconductor device including SGTs according to a second embodiment of the present invention.

FIGS. 2EA, 2EB and 2EC are a plan view and sectional structural views for explaining a method for manufacturing a pillar-shaped semiconductor device including SGTs according to a second embodiment of the present invention.

FIGS. 3A, 3B and 3C are a plan view and sectional structural views for explaining a method for manufacturing a pillar-shaped semiconductor device including SGTs according to a third embodiment of the present invention.

FIGS. 4AA, 4AB and 4AC are a plan view and sectional structural views for explaining a method for manufacturing a pillar-shaped semiconductor device including SGTs according to a fourth embodiment of the present invention.

FIGS. 4BA, 4BB and 4BC are a plan view and sectional structural views for explaining a method for manufacturing a pillar-shaped semiconductor device including SGTs according to a fourth embodiment of the present invention.

FIGS. 4CA, 4CB and 4CC are a plan view and sectional structural views for explaining a method for manufacturing a pillar-shaped semiconductor device including SGTs according to a fourth embodiment of the present invention.

FIG. 5 is a schematic structural view of an SGT of the related art.

FIG. 6 is a diagram of an SRAM cell circuit including SGTs of the related art.

### DESCRIPTION OF THE PREFERRED EMBODIMENTS

Hereinafter, methods for manufacturing a pillar-shaped semiconductor device according to embodiments of the present invention will be described with reference to the drawings.

### First Embodiment

Hereinafter, a method for manufacturing an SRAM circuit according to a first embodiment of the present invention will be described in the context of including SGTs with reference to FIG. 1AA to FIG. 1QC. Figures with the suffix A are plan views, figures with the suffix B are sectional structural views taken along line X-X′ in the figures with the suffix A, and figures with the suffix C are sectional structural views taken along line Y-Y′ in the figures with the suffix A.

As illustrated in FIGS. 1AA to 1AC, an N layer 2 (an example of “substrate” in the claims) is formed on a P layer 1 (an example of “substrate” in the claims) by epitaxial crystal growth to form a substrate. Subsequently, an N⁺ layer 3 (an example of “first impurity region” in the claims) and P⁺ layers 4a and 4b (examples of “second impurity region” in the claims) are formed at desired positions of a surface layer of the N layer 2, that is, the substrate surface. The N⁺ layer 3 and the P⁺ layers 4a and 4b are each formed by epitaxial crystal growth or ion implantation. The N⁺ layer 3 may be formed as a P⁺ layer 3 of the opposite conductivity type.

Hereinafter, in this and subsequent embodiments, this step will be described in the context where the impurity layer formed on the substrate surface is doped with N⁺ impurities.

Next, an i layer 6 (an example of “semiconductor pillar” in the claims), an N⁺ layer 8 (an example of “third impurity region” in the claims), and P⁺ layers 9a and 9b (examples of “fourth impurity region” in the claims) are formed each at a desired position by epitaxial crystal growth. Next, as illustrated in FIGS. 1BA to 1BC, for example, a mask semiconductor layer 7 formed of a SiN layer, next, for example, a silicon germanium (SiGe) mask semiconductor layer 10, and next, for example, a mask semiconductor layer 11 formed of a SiO₂ layer are sequentially deposited. The i layer 6 may be formed of N-type or P-type Si that contains donor or acceptor impurity atoms in a small amount.

Next, the SiO₂ mask semiconductor layer 11 is etched using band-shaped resist layers (not illustrated) formed by lithography and extending in a Y direction in plan view as masks. Thus, band-shaped SiO₂ mask semiconductor layers extending in the Y direction in plan view are formed. The band-shaped mask semiconductor layers are isotropically etched using the resist layers as masks such that the width of the band-shaped mask semiconductor layers is smaller than the width of the resist layers. Thus, band-shaped SiO₂ mask semiconductor layers 11a and 11b having a width smaller than the width of a narrowest resist layer that can be formed by lithography are formed. Subsequently, as illustrated in FIGS. 1Ca to 1CC, the SiGe mask semiconductor layer 10 is etched by, for example, anisotropic etching using the band-shaped SiO₂ mask semiconductor layers 11a and 11b as etching masks to form band-shaped SiGe mask semiconductor layers 10a and 10b.

Next, an amorphous Si layer 13 (not illustrated) is formed by, for example, chemical vapor deposition (CVD) so as to cover the entire surface, and the amorphous Si layer 13 is removed by anisotropic etching to form amorphous Si mask semiconductor layers 13a and 13b on both sides of the band-shaped SiGe mask semiconductor layer 10a and amorphous Si mask semiconductor layers 13c and 13d on both sides of the band-shaped SiGe mask semiconductor layer 10b, as illustrated in FIGS. 1Da to 1DC.

Next, the band-shaped SiO₂ mask semiconductor layers 11a and 11b and the band-shaped SiGe mask semiconductor layers 10a and 10b are removed. Thus, as illustrated in FIGS. 1EA to 1EC, the band-shaped amorphous Si mask semiconductor layers 13a, 13b, 13c, and 13d extending in the Y direction in plan view and aligned parallel to each other are formed on the mask semiconductor layer 7.

Next, a SiO₂ layer (not illustrated) is formed by FCVD so as to cover the entire surface. Subsequently, the SiO₂ layer is polished by CMP so that the upper surface thereof is flush with the upper surfaces of the band-shaped amorphous Si mask semiconductor layers 13a, 13b, 13c, and 13d, and next, for example, a SiN layer 16 and a SiO₂ mask semiconductor layer 17 are sequentially deposited. Next, as illustrated in FIGS. 1FA to 1FC, band-shaped SiO₂ mask semiconductor layers 17a and 17b extending in an X direction and aligned parallel to each other are formed on the SiN layer 16 using the same basic technique as the method by which the band-shaped amorphous Si semiconductor layers 13a, 13b, 13c, and 13d have been formed.

Next, the SiN layer 16 and the band-shaped amorphous Si semiconductor layers 13a, 13b, 13c, and 13d are etched by RIE etching using the band-shaped SiO₂ mask semiconductor layers 17a and 17b as masks. Subsequently, the remaining SiN layer 16 and SiO₂ layer 15 are removed. Thus, amorphous Si pillars 13aa, 13ab, 13ac, 13ad, 13ba, 13bb, 13bc, and 13bd are formed, and the SiN pillars 13ab and 13bc are removed as illustrated in FIGS. 1GA to 1GC.

Next, the SiN mask semiconductor layer 7 is etched using the amorphous semiconductor pillars 13aa, 13ac, 13ad, 13ba, 13bb, and 13bd as masks to form SiN mask semiconductor layers 7a, 7b, 7c, 7d, 7e, and 7f. Subsequently, the amorphous semiconductor pillars 13aa, 13ac, 13ad, 13ba, 13bb, and 13bd are removed. Subsequently, the N⁺ layers 8a, 8c, 8d, and 8f, the P⁺ layer 9b and 9e, and the i layer 6 are etched using the mask semiconductor layers 7a, 7b, 7c, 7d, 7e, and 7f as masks to form semiconductor pillars 6a, 6b, 6c, 6d, 6e, and 6f on the N⁺ layer 3 and the P⁺ layers 4a and 4b, as illustrated in FIGS. 1HA to 1HC, and next, a semiconductor pillar protection film 12 formed of, for example, a SiN layer is formed by FCVD so as to cover the entire surface. The material composition of the mask semiconductor layer 7 is selected in order to obtain accurate mask semiconductor layers 7a, 7b, 7c, 7d, 7e, and 7f.

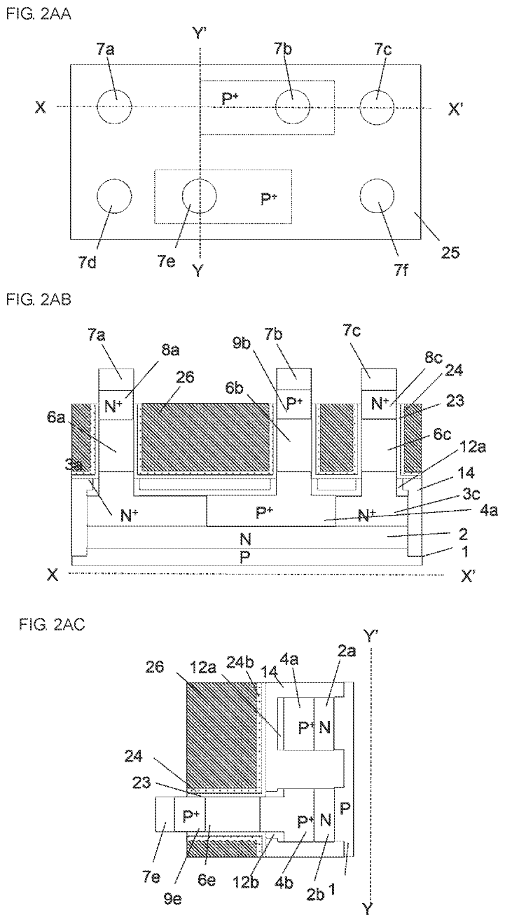

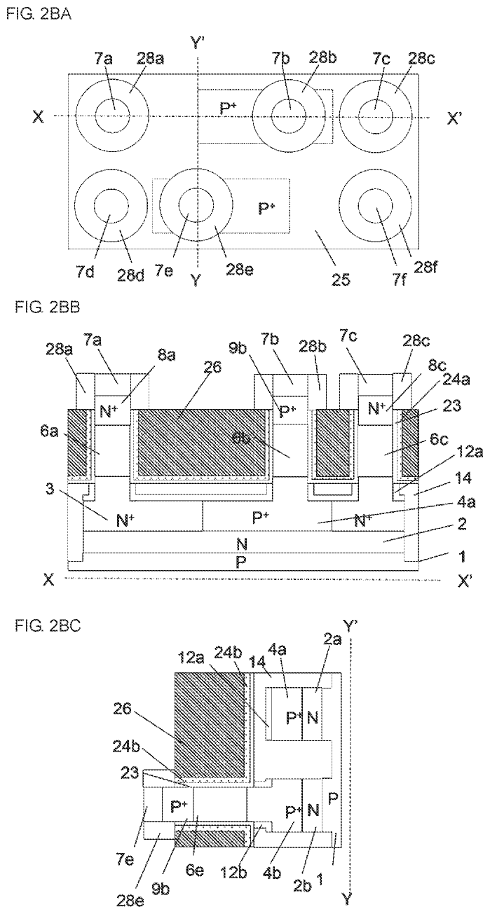

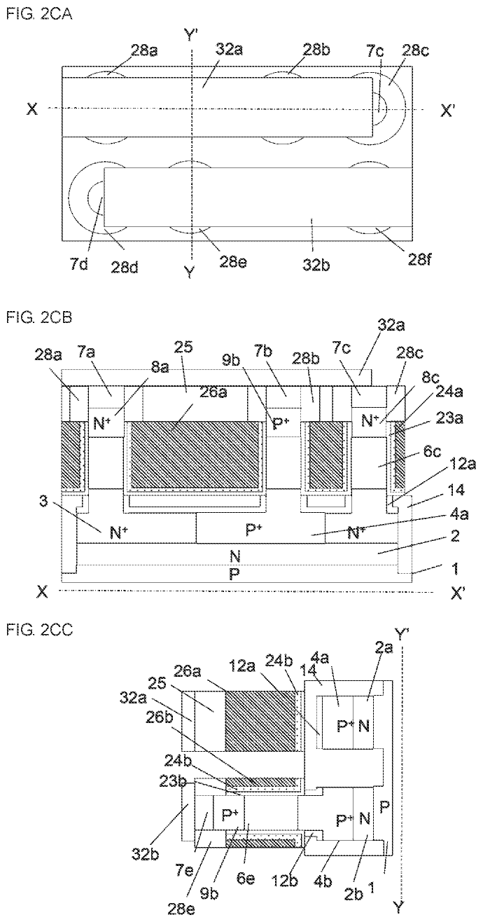

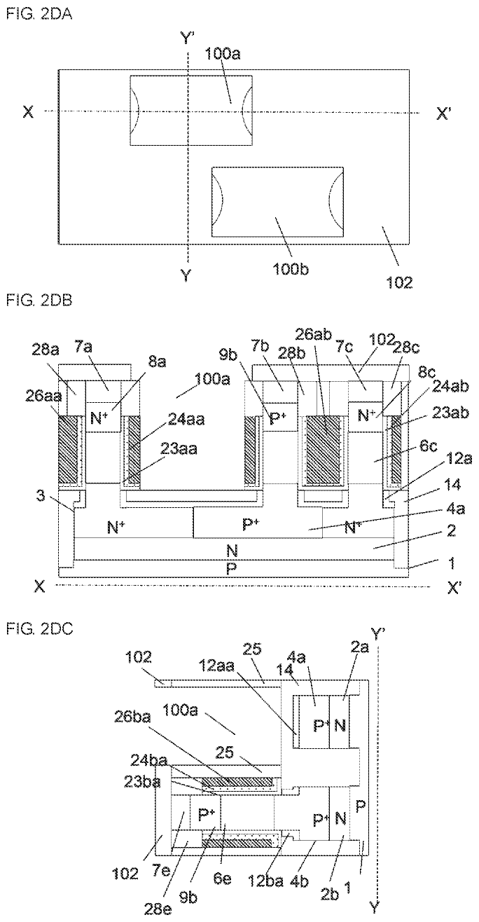

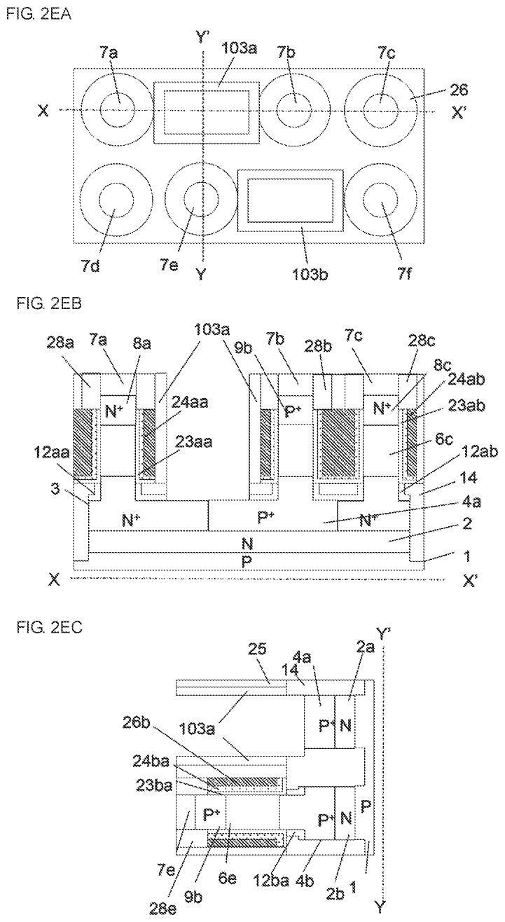

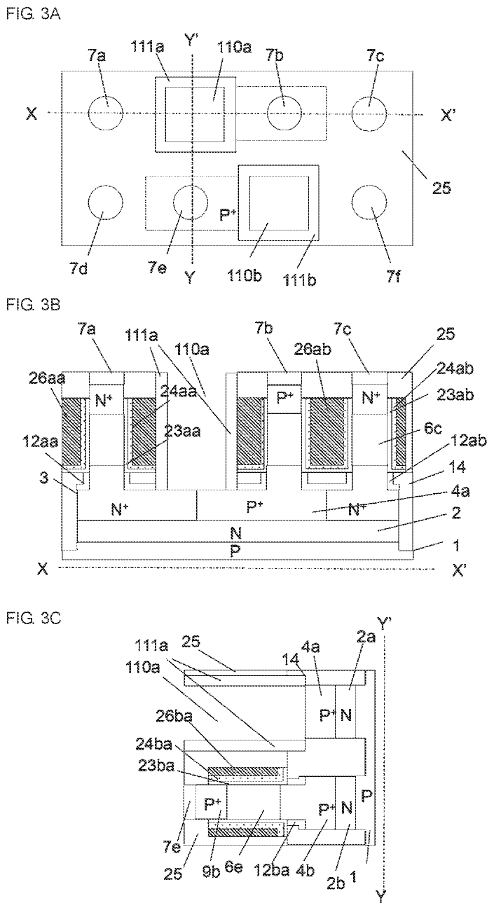

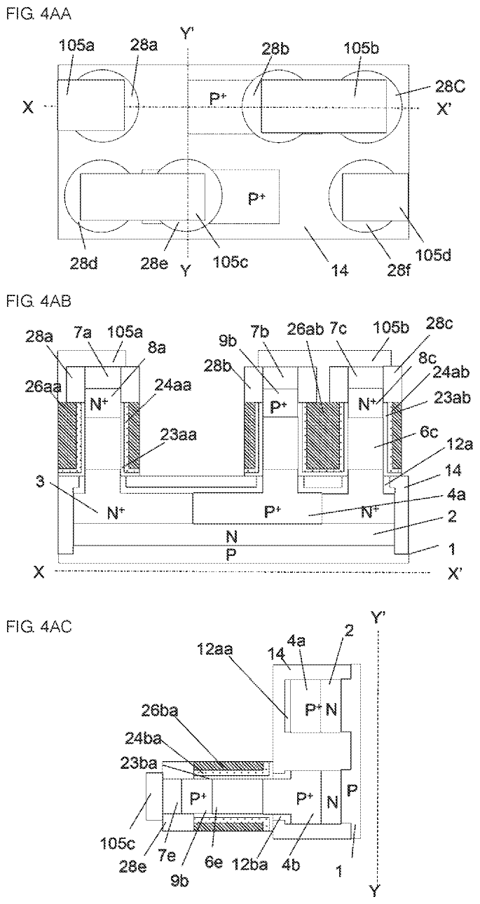

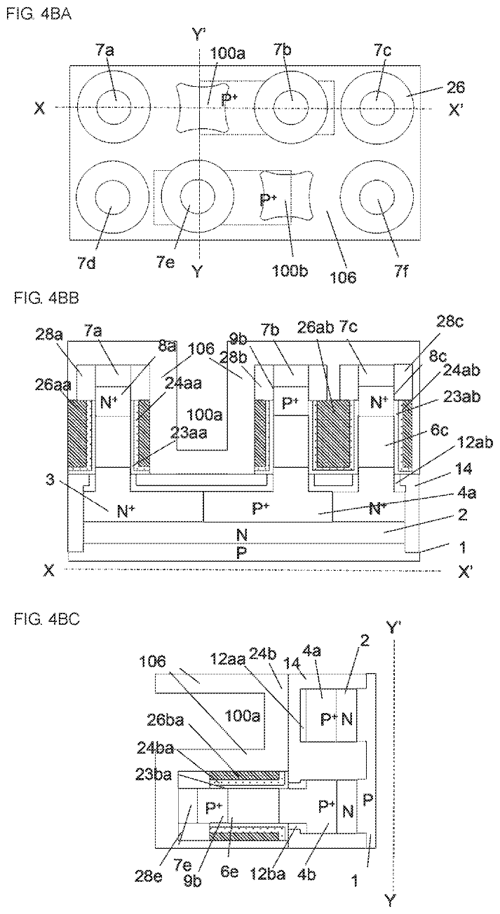

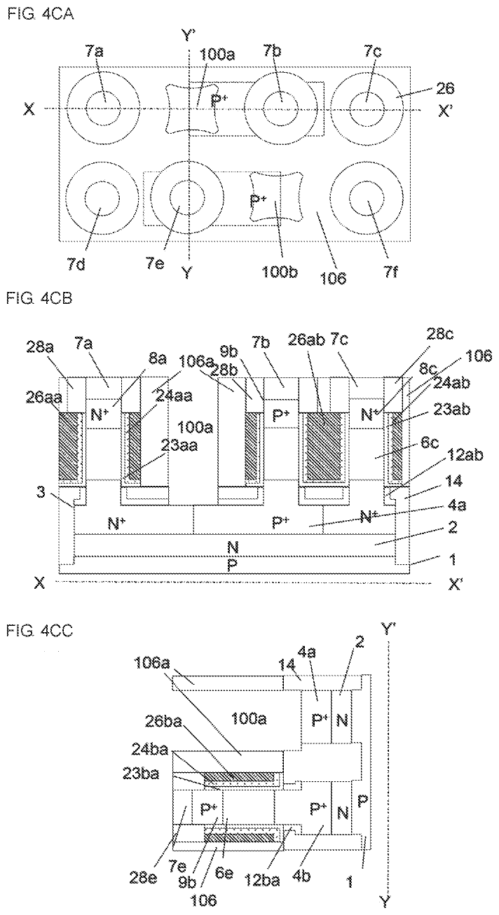

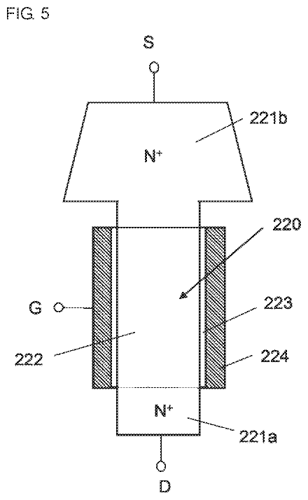

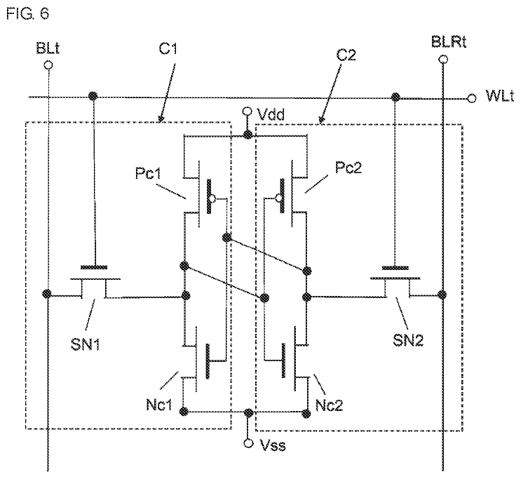

Next, the semiconductor pillar protection film 12 and the N⁺ layer 3, the P⁺ layer 4a, the N layer 2, and the P layer substrate 1 connecting to bottom portions of the semiconductor pillars 6a, 6b, and 6c are etched to form a semiconductor pillar base 18a constituted by an upper portion of the P layer substrate 1, an N layer 2a, N⁺ layers 3a and 3c (which are either third impurity layers or fourth impurity layers), and the P⁺ layer 4a (which is the fourth impurity layer when the N⁺ layer 3a is the third impurity layer, and is the third impurity layer when the N⁺ layer 3a is the fourth impurity layer). At the same time, the N⁺ layer 3, the P⁺ layer 4b, the N layer 2, and the P layer substrate 1 connecting to bottom portions of the semiconductor pillars 6d, 6e, and 6f are etched to form a semiconductor pillar base 18b constituted by an upper portion of the P layer substrate 1, an N layer 2b, an N⁺ layer 3d (which is not illustrated and is either the third impurity layer or the fourth impurity layer), an N⁺ layer 3f (not illustrated), and the P⁺ layer 4b (which is the fourth impurity layer when the N⁺ layer 3d is the third impurity layer, and is the third impurity layer when the N⁺ layer 3d is the fourth impurity layer). Subsequently, as illustrated in FIGS. 11A to 11C, a SiO₂ layer 14 is formed at the outer peripheries of the N⁺ layers 3a, 3c, 3d, and 3f, the P⁺ layers 4a and 4b, and the N layers 2a and 2b and on the P layer substrate 1.

Next, the semiconductor pillar protection film 12 exposed on the surface is removed. As illustrated in FIGS. 1JA to 1JC, a HfO₂ layer 23 serving as a gate oxide film, a work function metal TiN layer 24 serving as a gate electrode, and a W layer 26 are deposited by ALD so as to cover the entire surface and, as illustrated in FIGS. 1JA to 1JC, polished throughout by CMP so that the upper surfaces thereof are flush with the upper surfaces of the mask semiconductor layers 7a, 7b, 7c, 7d, 7e, and 7f.

Next, as illustrated in FIGS. 1KA to 1KC, the W layer 26, the TiN layer 24, and the HfO₂ layer 23 are etched by lithography and RIE to form a TiN layer 24a and a W layer 26a that surround the semiconductor pillars 6a, 6b, and 6c and a TiN layer 24b and a W layer 26b that surround the semiconductor pillars 6d, 6e, and 6f, and the HfO₂ layer 23, the TiN layers 24a and 24b, and the W layers 26a and 26b are etched back such that the surfaces of the W layers 26a and 26b are located above the lower surfaces of the N⁺ layers 8a, 8c, 8d, and 8f and the P⁺ layers 9b and 9e in side view.

Next, a SiO layer 25 is formed by FCVD so as to cover the entire surface and polished throughout by CMP so that the upper surface thereof is flush with the upper surfaces of the mask semiconductor layers 7a, 7b, 7c, 7d, 7e, and 7f. Subsequently, two contact holes are formed in the SRAM cell. Specifically, photoresist opening regions (not illustrated) are formed by lithography between the semiconductor pillars 6a and 6b and between the semiconductor pillars 6e and 6f, and as illustrated in FIGS. 1LA to 1LC, the SiO layer 25, the W layers 26a and 26b, the TiN layers 24a and 24b, and the HfO₂ layers 23a and 23b are etched by RIE using the photoresist opening regions as masks to form a gate electrode TiN layer 24aa and a W layer 26aa that surround the semiconductor pillar 6a, a gate electrode TiN layer 24ab and a W layer 26ab that surround the semiconductor pillars 6b and 6c, a gate electrode TiN layer 24ba and a W layer 26ba that surround the semiconductor pillars 6d and 6e, and a gate electrode TiN layer 24bb and a W layer 26bb that surround the semiconductor pillar 6f and also form hole regions 100a and 100b.

Next, an insulating layer 101 is formed by FCVD so as to cover the entire surface, and the insulating layer 101 is etched by RIE to form sidewalls 101a and 101b on the side walls of the hole regions 100a and 100b, respectively, as illustrated in FIGS. 1MA to 1MC.

Next, semiconductor pillar protection films 12a and 12b and the SiO₂ layer 14 are etched by RIE using the sidewalls 101a and 101b as hard masks. Next, a barrier metal 27 and a W layer 29 for contact holes are sequentially deposited and, as illustrated in FIGS. 1NA to 1NC, polished throughout by CMP so that the upper surfaces thereof are flush with the upper surfaces of the mask semiconductor layers 7a, 7b, 7c, 7d, 7e, and 7f, thereby forming 27a, 27b, 29a, and 29b.

Next, an interlayer insulating film 30 is formed by CVD so as to cover the entire surface, and photoresist opening regions (not illustrated) are formed on the mask semiconductor layers 7a, 7b, 7c, 7d, 7e, and 7f by lithography. The interlayer insulating film 30 is etched by RIE using the photoresist opening regions as masks to expose (not illustrated) the mask semiconductor layers 7a, 7b, 7c, 7d, 7e, and 7f, and the exposed mask semiconductor layers 7a, 7b, 7c, 7d, 7e, and 7f are removed. Next, a barrier metal for upper electrode formation (not illustrated) and a W layer 33 are formed so as to cover the entire surface and, as illustrated in FIGS. 1PA to 1PC, polished throughout by CMP so that the upper surfaces thereof are flush with the upper surface of the interlayer insulating film 30, thereby forming 33a, 33b, 33c, 33d, 33e, and 33f.

This step may be carried out as follows: a thin TiN layer and a W layer are formed prior to a SiO₂ layer 30 and etched by lithography and reactive ion etching (RIE) such that the TiN layer and the W layer are left on at least part of 8a, 8c, 8d, 8f, 9b, and 9e to form 33a, 33b, 33c, 33d, 33e, and 33f, after which the SiO₂ layer 30 is formed by CVD so as to cover the entire surface and polished throughout by CMP. This polishing may be performed until the surface of the W layer is exposed or may be performed such that the SiO₂ layer 30 remains on the W layer.

Next, a connection wiring metal layer XC1 is formed through a contact hole C1 formed on the upper surfaces of the TiN layer 27a and the W layer 29a and the side wall of the W layer 26ba. At the same time, a connection wiring metal layer XC2 (not illustrated) is formed through a contact hole C2 formed on the upper surfaces of the TiN layer 27b and the W layer 29b and the side wall of the W layer 26ab.

Subsequently, a SiO₂ layer 36 having a flat upper surface is formed so as to cover the entire surface. Subsequently, a word wiring metal layer WL is formed through contact holes C3 and C4 respectively formed on the W layers 26aa and 26bb. Next, a SiO₂ layer 37 having a flat upper surface is formed so as to cover the entire surface. Subsequently, a power supply wiring metal layer Vdd is formed through contact holes C5 and C6 respectively formed on the W layer 33b on the P⁺ layer 9b and the W layer 33e on the P⁺ layer 9e. Subsequently, a ground wiring metal layer Vss1 is formed through a contact hole C7 formed on the W layer 33c on the N⁺ layer 8c. At the same time, a ground wiring metal layer Vss2 is formed through a contact hole C8 formed on the W layer 33d on the N⁺ layer 8d. Subsequently, a SiO₂ layer 39 having a flat upper surface is formed so as to cover the entire surface. Subsequently, a bit output wiring metal layer BL and an inverted bit output wiring metal layer RBL are respectively formed through a contact hole C10 formed on the W layer 33f on the N⁺ layer 8f and a contact hole C9 formed on the W layer 33a on the N⁺ layer 8a. Thus, an SRAM cell circuit is formed on the P layer substrate 1 as illustrated in FIGS. 1QA to 1QC. In this SRAM circuit, load SGTs are formed in the Si pillars 6b and 6e, drive SGTs are formed in the Si pillars 6c and 6d, and selection SGTs are formed in the Si pillars 6a and 6f.

As illustrated in FIGS. 1QA to 1QC, the N⁺ layers 3a, 3c, 3d, and 3f and the P⁺ layers 4a and 4b serving as sources or drains of SGTs are formed below the Si pillars 6a to 6f so as to be connected to each other on the N layers 2a and 2b. Instead of this, the N⁺ layers 3a, 3c, 3d, and 3f and the P⁺ layers 4a and 4b may be formed in bottom portions of the Si pillars 6a to 6f, and the N⁺ layers 3a, 3c, 3d, and 3f and the P⁺ layers 4a and 4b may be connected to each other through a metal layer or an alloy layer.

Alternatively, the N⁺ layers 3a, 3c, 3d, and 3f and the P⁺ layers 4a and 4b may be formed so as to be connected to the side surfaces of bottom portions of the Si pillars 6a to 6f. As described above, the N⁺ layers 3a, 3c, 3d, and 3f and the P⁺ layers 4a and 4b serving as sources or drains of SGTs may be formed inside bottom portions of the Si pillars 6a to 6f or may be formed at the outer peripheries of the Si pillars 6a to 6f so as to be in contact with the outer side surfaces thereof, and may be electrically connected to each other through another conductor material. The same applies to other embodiments according to the present invention.

To increase the degree of integration of a circuit including SGTs, the separation distance between semiconductor pillars should necessarily be small. For example, in this embodiment, the distances between the semiconductor pillars 6a, 6b, and 6c are small. Accordingly, the distances between the semiconductor pillars 6a and 6b and the contact holes adjacent thereto are small, so that the following problems occur.

### Problem 1

The gate electrodes 26aa and 26ab disposed so as to surround the semiconductor pillars 6a and 6b, respectively, and the contact hole conductors 27a and 28b adjacent thereto may be electrically short-circuited to cause a malfunction.

### Problem 2

If the contact holes are formed small in order to avoid such an electrical short circuit as described above, the contact resistance may increase, thus resulting in degradation in performance such as a decrease in operating speed.

To overcome the above problems, the manufacturing method according to the first embodiment has the following features.
1. The contact hole 100a adjacent to the semiconductor pillars 6a and 6b is formed in the following manner: the gate electrode 26a existing in a region where the contact hole 100a is to be formed is removed by RIE etching, and the gate electrodes 26aa and 26ab are separately formed; the sidewall 101a, which is an insulating film, is formed on the side walls of the gate electrodes 26aa and 26ab; and the contact hole 100a is formed using the sidewall 101a as a hard mask. Due to this method, it is not necessary to preliminarily provide an alignment margin required in forming the contact hole in a photolithographic process, and electrical short-circuiting can be avoided.
2. According to the manufacturing method according to the first embodiment, performance degradation such as an increase in contact resistance resulting from a reduction in size of the contact hole 100a to avoid electrical short-circuiting can be avoided.
3. In this embodiment, an SRAM cell composed of six SGTs has been described. The present invention is also applicable to an SRAM cell composed of eight SGTs. In such an SRAM cell composed of eight SGTs, two rows aligned in the Y direction are each constituted by four SGTs. Among the four SGTs, two SGTs for load or drive are disposed adjacent to each other. In this case, gate electrodes of three SGTs for load and drive disposed side by side are connected to each other, and impurity layers in upper portions of the adjacent SGTs for load and drive must be separately formed. Since the relationship between the adjacent SGTs for load and drive is the same as that in the SRAM cell composed of six SGTs, a high-density SRAM cell composed of eight SGTs can be formed by using the method according to this embodiment. The present invention is also applicable to the formation of other SRAM cells composed of a plurality of SGTs.
4. In this embodiment, an example in which the present invention is applied to an SRAM cell has been described. An inverter circuit that is most commonly used in a logic circuit formed on the same chip is composed of at least two N-channel SGTs and a P-channel SGT, and gate electrodes of the N-channel SGTs and the P-channel SGT are connected to each other. Impurity regions in upper portions of the two N-channel SGTs and the P-channel SGT must be separated from each other. Thus, the relationship between a load SGT and a drive SGT in an SRAM cell and the relationship between N-channel SGTs and a P-channel SGT in an inverter circuit are the same. This indicates that a high-density microprocessor circuit can be achieved by applying the present invention to a microprocessor circuit including, for example, an SRAM cell region and a logic circuit region.
5. In this embodiment, the Si pillars 6a to 6f that are circular in plan view are formed. For the shapes of some or all of the Si pillars 6a to 6f in plan view, shapes such as a circular shape, an elliptical shape, and a shape elongated in one direction can be easily formed. Also in a logic circuit region formed apart from an SRAM region, Si pillars having different shapes in plan view can be formed to coexist in the logic circuit region, depending on the logic circuit design. This enables achievement of a high-density and high-performance microprocessor circuit.

### Second Embodiment

Hereinafter, a method for manufacturing an SRAM circuit including SGTs according to a second embodiment of the present invention will be described with reference to FIG. 2AA to FIG. 2EC. Figures with the suffix A are plan views, figures with the suffix B are sectional structural views taken along line X-X′ in the figures with the suffix A, and figures with the suffix C are sectional structural views taken along line Y-Y′ in the figures with the suffix A.

The steps illustrated in FIG. 1AA to FIG. 1JC of the first embodiment are performed, and the W layer 26 is then etched back such that the surface thereof is located above the lower surfaces the N⁺ layers 8a, 8c, 8d, and 8f and the P⁺ layers 9b and 9e, as illustrated in FIGS. 2AA to 2AC.

Next, a SiN layer 28 having a thickness that is the same as the desired gate electrode thickness is formed by FCVD so as to cover the entire surface, and the SiN layer 28 is etched by RIE to form sidewalls 28a, 28b, 28c, 28d, 28e, and 28f, as illustrated in FIGS. 2BA to 2BC.

Next, a SiO layer 25 is formed so as to cover the entire surface and polished throughout by CMP so that the upper surface thereof is flush with the upper surfaces of the mask semiconductor layers 7a, 7b, 7c, 7d, 7e, and 7f. The SiO layer 25, the W layer 26, the TiN layer 24, and the HfO₂ layer 23 are etched by RIE using photoresists 32a and 32b formed by lithography and the sidewalls 28a, 28b, 28c, 28d, 28e, and 28f as masks to form a gate electrode TiN layer 24a and a W layer 26a that surround the semiconductor pillars 6a, 6b, and 6c and a gate electrode layer 24b and a W layer 26b that surround the semiconductor pillars 6d, 6e, and 6f, as illustrated in FIGS. 2CA to 2CC.

Next, two contact holes are formed in the SRAM cell as follows: opening regions of a photoresist 102 are formed by lithography between the semiconductor pillars 6a and 6b and between the semiconductor pillars 6e and 6f, and as illustrated in FIGS. 2DA to 2DD, the SiO layer 25, the W layers 26a and 26b, the TiN layers 24a and 24b, and the HfO₂ layer 23 are etched by RIE etching using the photoresist 102 and the sidewalls 28a, 28b, 28e, and 28f as masks to form a gate electrode TiN layer 24aa and a W layer 26aa that surround the semiconductor pillar 6a, a gate electrode TiN layer 24ab and a W layer 26ab that surround the semiconductor pillars 6b and 6c, a gate electrode TiN layer 24ba and a W layer 26ba that surround the semiconductor pillars 6d and 6e, and a gate electrode TiN layer 24bb and a W layer 26bb that surround the semiconductor pillar 6f and also form hole regions 100a and 100b.

Next, after the photoresist 102 is peeled off, an insulating layer 103 is formed by FCVD so as to cover the entire surface, and the insulating layer 103 is etched by RIE to form sidewalls 103a and 103b on the side walls of the hole regions 100a and 100b, respectively. Using the sidewalls 103a and 103b as hard masks, the SiO₂ layer 14 and the semiconductor pillar protection films 12a and 12b are etched by RIE, as illustrated in FIGS. 2EA to 2EC.

The subsequent steps are the same as those illustrated in FIGS. 1NA to 1QC of the first embodiment.

This embodiment has the following features.

In forming the gate electrodes 26aa, 26ab, 26ba, and 26bb, the SiO layer sidewalls 28a, 28b, 28c, 28d, 28e, and 28f formed at top portions of the semiconductor pillars and the photoresist are used. Because of this, variation in size in the lateral direction of each gate electrode is reduced. Together with this, variation in both the size and position of openings of the contact holes 100a and 100b is also reduced, and variation in transistor properties and contact resistance is reduced.

### Third Embodiment

Hereinafter, a method for manufacturing an SRAM circuit including SGTs according to a third embodiment of the present invention will be described with reference to FIGS. 3A to 3C. Figures with the suffix A are plan views, figures with the suffix B are sectional structural views taken along line X-X′ in the figures with the suffix A, and figures with the suffix C are sectional structural views taken along line Y-Y′ in the figures with the suffix A.

The steps illustrated in FIG. 1AA to FIG. 1LC of the first embodiment are performed. Subsequently, the SiO₂ layer 14 and the semiconductor pillar protection films 12a and 12b are etched by RIE to form a gate electrode TiN layer 24aa and a W layer 26aa that surround the semiconductor pillar 6a, a gate electrode TiN layer 24ab and a W layer 26ab that surround the semiconductor pillars 6b and 6c, a gate electrode TiN layer 24ba and a W layer 26bb that surround the semiconductor pillars 6d and 6e, and a gate electrode TiN layer 24bb and a W layer 26bb that surround the semiconductor pillar 6f, and at the same time, the HfO₂ layer 23, the SiO₂ layer 14, and the SiN layer 12 are etched to expose the surfaces of the N⁺ layer 3a and the P⁺ layer 4a, which are impurity regions, thereby forming hole regions 110a and 110b. Next, an insulating layer 111 is formed by FCVD so as to cover the entire surface, and the insulating layer 111 is etched by RIE to form sidewalls 111a and 111b on the side walls of the hole regions 110a and 110b, respectively, as illustrated in FIGS. 3A to 3C.

The subsequent steps are the same as those illustrated in FIGS. 1NA to 1QC of the first embodiment.

This embodiment has the following features.

In forming the contact holes, the SiO₂ layer 14 and the semiconductor pillar protection films 12a and 12b are also etched to form the sidewalls 111a and 111b, and thus the SiO₂ layer 14 is not exposed on the side walls of the contact holes. Because of this, the SiO₂ layer 14 is not etched in the pretreatment for the deposition of the barrier metal 27 in the subsequent step, and thus leak currents between the contact holes and the gate electrodes are reduced.

### Fourth Embodiment

Hereinafter, a method for manufacturing an SRAM circuit including SGTs according to a fourth embodiment of the present invention will be described with reference to FIG. 4AA to FIG. 4CC. Figures with the suffix A are plan views, figures with the suffix B are sectional structural views taken along line X-X′ in the figures with the suffix A, and figures with the suffix C are sectional structural views taken along line Y-Y′ in the figures with the suffix A.

The steps illustrated in FIG. 1AA to FIG. 1JC of the first embodiment and the steps illustrated in FIG. 2AA to FIG. 2BC of the second embodiment are performed. Next, the TiN layer 24, the W layer 26, and the HfO₂ layer 23 are etched using photoresists 105a, 105b, 105c, and 105d formed by lithography and the SiN layer sidewalls 28a, 28b, 28c, 28d, 28e, and 28f to form gate electrodes 26aa, 24aa, 26ab, 24ab, 26ba, 24ba, 26bb, and 24bb, as illustrated in FIGS. 4AA to 4AC.

Next, a SiO layer 106 is formed by FCVD so as to cover the entire surface. At this time, the thickness of the SiO layer 106 is set such that the space between the adjacent gate electrodes 26aa and 26ba and the space between the adjacent gate electrodes 26ab and 26bb are filled with the SiO layer 106 and that the space between the gate electrodes 26aa and 26ab and the space between the gate electrodes 26ba and 26bb where contact holes 100a and 100b are to be formed are not filled with the SiO layer 106.

Next, the SiO layer 106 is etched by RIE to form a SiO layer sidewall 106a on the side walls of the gate electrode 26aa and the SiN layer 28a thereon and the side walls of the gate electrode 26ab and the SiN layer 28b thereon, form a SiO layer sidewall 106b on the side walls of the gate electrode 26ba and the SiN layer 28e thereon and the side walls of the gate electrode 26bb and the SiN layer 28f thereon, and also form contact holes 100a and 100b, as illustrated in FIGS. 4CA to 4CC.

The subsequent steps are the same as those illustrated in FIGS. 1NA to 1QC of the first embodiment.

This embodiment has the following features.

The contact holes are formed without using a photolithographic mask but in a self-aligned manner due to the sidewalls of the insulating layer 106 formed on the gate electrode side walls. Because of this, performance degradation such as electrical short-circuiting due to misalignment and an increase in contact resistance due to undersized contact holes can be further avoided.

In the embodiments according to the present invention, one SGT is formed in one semiconductor pillar. The present invention is also applicable to the formation of a circuit in which two or more SGTs are formed in one semiconductor pillar.

In the first embodiment, the semiconductor pillars 6a to 6f are formed. Alternatively, semiconductor pillars made of other semiconductor materials may be formed. The same applies to other embodiments according to the present invention.

The N⁺ layers 3a, 3c, 3d, 3f, 8a, 8c, 8d, and 8f and the P⁺ layers 4a, 4b, 9b, and 9e in the first embodiment may be formed of Si or other semiconductor material layers containing donor or acceptor impurities. The same applies to other embodiments according to the present invention.

The SiN layer 12 at the outer peripheries of the semiconductor pillars 6a to 6f in the first embodiment may be replaced with another material layer having a single-layer structure or a multilayer structure and containing an organic material or an inorganic material as long as the material is suitable for the object of the present invention. The same applies to other embodiments according to the present invention.

In the first embodiment, the mask material layer 7 is formed of a SiO₂ layer, an aluminum oxide (Al₂O₃, hereinafter referred to as AlO) layer, and a SiO₂ layer. The mask material layer 7 may be replaced with another material layer having a single-layer structure or a multilayer structure and containing an organic material or an inorganic material as long as the material is suitable for the object of the present invention. The same applies to other embodiments according to the present invention.

The wiring metal layers XC1, XC2, WL, Vdd, Vss, BL, and RBL in the first embodiment may each be made of not only a metal but also an alloy or a conductive material such as a semiconductor containing acceptor or donor impurities in a large amount, and may have a single-layer structure or a multilayer structure. The same applies to other embodiments according to the present invention.

In the first embodiment, the TiN layers 24aa, 24ab, 24ba, and 24bb are used as gate metal layers, as illustrated in FIGS. 1NA to 1NC. The TiN layers 24aa, 24ab, 24ba, and 24bb may each be any material layer having a single-layer structure or a multilayer structure as long as the material is suitable for the object of the present invention. The TiN layers 24aa, 24ab, 24ba, and 24bb may each be formed of a conductor layer having at least a desired work function, such as a metal layer having a single-layer structure or a multilayer structure. Another conductive layer such as a W layer may be formed outside the TiN layers. In this case, the W layer serves as a metal wiring layer that connects the gate metal layers together. Instead of the W layer, a metal layer having a single-layer structure or a multilayer structure may be used. Furthermore, the HfO₂ layer 23 is used as a gate insulating layer, but other material layers each having a single-layer structure or a multilayer structure may be used. The same applies to other embodiments according to the present invention.

In the first embodiment, the shape of the semiconductor pillars 6a to 6f in plan view is a circular shape. For the shapes of some or all of the semiconductor pillars 6a to 6f in plan view, shapes such as a circular shape, an elliptical shape, and a shape elongated in one direction can be easily formed. Also in a logic circuit region formed apart from an SRAM region, semiconductor pillars having different shapes in plan view can be formed to coexist in the logic circuit region, depending on the logic circuit design. The same applies to other embodiments according to the present invention.

In the first embodiment, the N⁺ layers 3a, 3c, 3d, and 3f and the P⁺ layers 4a and 4b are formed so as to be connected to the bottom portions of the semiconductor pillars 6a to 6f. A metal layer or an alloy layer formed of silicide or the like may be formed on the upper surfaces of the N⁺ layers 3a, 3c, 3d, 3f and the P⁺ layers 4a and 4b. As described above, the formation of impurity regions connecting to the bottom portions of the semiconductor pillars 6a to 6f and impurity-layer-combining regions that connect these impurity layers together may be determined from the viewpoint of design and production. The N⁺ layers 3a, 3c, 3d, and 3f and the P⁺ layers 4a and 4b serve as impurity layers and also as impurity-layer-combining regions. The same applies to other embodiments according to the present invention.

In the first embodiment, SGTs are formed on the P layer substrate 1. The P layer substrate 1 may be replaced with a silicon-on-insulator (SOI) substrate. Alternatively, any other material substrate may be used as long as it serves as a substrate. The same applies to other embodiments according to the present invention.

In the first embodiment, SGTs in which sources and drains are formed on the upper and lower sides of the semiconductor pillars 6a to 6f using the N⁺ layers 3a, 3c, 3d, and 3f, the P⁺ layers 4a and 4b, the N⁺ layers 8a, 8c, 8d, and 8f, and the P⁺ layers 9b and 9e, which have conductivity of the same polarity, have been described. The present invention is also applicable to tunneling SGTs including sources and drains having different polarities. The same applies to other embodiments according to the present invention.

In a vertical NAND-type flash memory circuit, a plurality of memory cells are formed in the vertical direction. Each memory cell includes a semiconductor pillar serving as a channel, and a tunnel oxide layer, a charge storage layer, an interlayer insulating layer, and a control conductor layer that surround the semiconductor pillar. Semiconductor pillars at both ends of these memory cells include a source line impurity layer corresponding to a source and a bit line impurity layer corresponding to a drain. When one of the memory cells on both sides of a certain memory cell serves as a source, the other serves as a drain. Thus, the vertical NAND-type flash memory circuit is an SGT circuit. Therefore, the present invention is also applicable to a circuit in which a NAND-type flash memory circuit coexists.

Similarly, in a magnetic memory circuit and a ferroelectric memory circuit, the present invention is applicable to an inverter and a logic circuit used inside or outside a memory cell region.

Various embodiments and modifications of the present invention can be made without departing from the broad spirit and scope of the present invention. The foregoing embodiments are illustrative of examples of the present invention and are not intended to limit the scope of the present invention. The foregoing examples and modifications can be combined in any manner. Furthermore, the foregoing embodiments fall within the scope of the technical idea of the present invention even if some elements are excluded from those embodiments as needed.

The method for manufacturing a pillar-shaped semiconductor device according to the present invention can provide a high-density pillar-shaped semiconductor device.

What is claimed is:

1. A method for manufacturing a pillar-shaped semiconductor device that includes, on a substrate, a first semiconductor pillar and a second semiconductor pillar adjacent to the first semiconductor pillar, a first gate insulating layer surrounding the first semiconductor pillar, a second gate insulating layer surrounding the second semiconductor pillar, a first gate conductor layer surrounding the first gate insulating layer, a second gate conductor layer surrounding the second gate insulating layer, a first impurity region connected to a lower portion of the first semiconductor pillar, a second impurity region connected to a lower portion of the second semiconductor pillar, a third impurity region connected to a top portion of the first semiconductor pillar, a fourth impurity region connected to a top portion of the second semiconductor pillar, and a first SGT in which the first semiconductor pillar between the first impurity region and the third impurity region serves as a channel and a second SGT in which the second semiconductor pillar between the second impurity region and the fourth impurity region serves as a channel, and that has, between the first SGT and the second SGT in plan view, a first contact hole in electrical contact with at least the first or second impurity region, the method comprising:
a step of forming the first semiconductor pillar on the first impurity region and forming the second semiconductor pillar on the second impurity region;
a step of forming the first gate insulating layer surrounding the first semiconductor pillar and forming the second gate insulating layer surrounding the second semiconductor pillar;
a step of forming a gate conductor film so as to cover an entire surface;
a step of polishing the gate conductor film until surfaces of the top portions of the first and second semiconductor pillars are exposed;
a step of patterning an etching-mask opening region by photolithography at an inner-side region of the gate conductor film disposed between the first and second semiconductor pillars in plan view;
a step of etching the gate conductor film using the etching-mask opening region as a mask to form the first contact hole and separate the gate conductor film into the first gate conductor layer and the second gate conductor layer by the first contact hole;
a step of forming a first insulating layer so as to cover an entire surface, and anisotropically etching the first insulating layer to form a first sidewall on side walls of the first and second gate conductor layers and anisotropically etching an insulating layer including the first and second gate insulating layers and present on the substrate to expose a surface of at least the first or second impurity region; and
a step of forming a contact conductor layer so as to fill the first contact hole surrounded by the first sidewall.

2. The method for manufacturing a pillar-shaped semiconductor device according to claim 1, comprising:
a step of, after the formation of the gate conductor film, polishing the gate conductor film until surfaces of the top portions of the first and second semiconductor pillars are exposed;
a step of recess etching the gate conductor film such that a surface of the gate conductor film is located above lower surfaces of the third and fourth impurity regions;
a step of forming a second insulating layer so as to cover an entire surface and then anisotropically etching the second insulating layer to form a second sidewall around the top portions of the first and second semiconductor pillars exposed on the gate conductor film;
a step of forming the gate conductor film so as to connect and surround both of the first and second semiconductor pillars in plan view by anisotropic etching using a photoresist formed by photolithography and the second sidewall;
the step of patterning an etching-mask opening region by photolithography at an inner-side region of the gate conductor film disposed between the first and second semiconductor pillars in plan view;
a step of anisotropically etching the gate conductor film at the etching-mask opening region using the photoresist and the second sidewall to separate the gate conductor film into the first gate conductor layer and the second gate conductor layer; and
a step of forming a first insulating layer so as to cover an entire surface, and anisotropically etching the first insulating layer to form the first sidewall on side walls of the first and second gate conductor layers and anisotropically etching an insulating layer including the first and second gate insulating layers and present on the substrate to expose a surface of at least the first or second impurity region.

3. The method for manufacturing a pillar-shaped semiconductor device according to claim 1, comprising, after the step of anisotropically etching the gate conductor film at the etching-mask opening region and an insulating layer including the first and second gate insulating layers and present on the substrate to expose a surface of at least the first or second impurity region,
a step of forming a first insulating layer so as to cover an entire surface and anisotropically etching the first insulating layer to form the first sidewall on a side wall of the first contact hole.

4. A method for manufacturing a pillar-shaped semiconductor device that includes, on a substrate, a first semiconductor pillar and a second semiconductor pillar adjacent to the first semiconductor pillar, a first gate insulating layer surrounding the first semiconductor pillar, a second gate insulating layer surrounding the second semiconductor pillar, a first gate conductor layer surrounding the first gate insulating layer, a second gate conductor layer surrounding the second gate insulating layer, a first impurity region connected to a lower portion of the first semiconductor pillar, a second impurity region connected to a lower portion of the second semiconductor pillar, a third impurity region connected to a top portion of the first semiconductor pillar, a fourth impurity region connected to a top portion of the second semiconductor pillar, and a first SGT in which the first semiconductor pillar between the first impurity region and the third impurity region serves as a channel and a second SGT in which the second semiconductor pillar between the second impurity region and the fourth impurity region serves as a channel, and that has, between the first SGT and the second SGT in plan view, a first contact hole in electrical contact with at least the first or second impurity region and the first and second gate conductor layers, the method comprising:
a step of forming the first semiconductor pillar on the first impurity region and forming the second semiconductor pillar on the second impurity region;
a step of forming the first gate insulating layer surrounding the first semiconductor pillar and forming the second gate insulating layer surrounding the second semiconductor pillar;
a step of forming a gate conductor film so as to cover an entire surface;
a step of polishing the gate conductor film until surfaces of the top portions of the first and second semiconductor pillars are exposed;
a step of recess etching the gate conductor film such that a surface of the gate conductor film is located above lower surfaces of the third and fourth impurity regions;
a step of forming a second insulating layer so as to cover an entire surface and then anisotropically etching the second insulating layer to form a second sidewall around the top portions of the first and second semiconductor pillars exposed on the gate conductor film;
a step of forming the gate conductor film so as to surround each of the first and second semiconductor pillars in plan view by anisotropic etching using a photoresist formed by photolithography and the second sidewall;
a step of forming a third insulating layer so as to cover an entire surface; and
a step of anisotropically etching the third insulating layer to form a first sidewall on side walls of the first gate conductor layer and the second gate conductor layer in a region where the first gate conductor layer and the second gate conductor layer face each other, and remove an insulating layer including the first and second gate insulating layers and present on the substrate to expose a surface of at least the first or second impurity region, thereby forming, as the first contact hole, a region surrounded by the first sidewall.
